(19) United States
(12) Patent Application Publication
(10) Pub. No.: US 2026/0068714 A1
(43) Pub. Date: Mar. 5, 2026

(54) PACKAGE SUBSTRATE

(71) Applicant: SAMSUNG ELECTRONICS CO., LTD., SUWON-SI (KR)

(72) Inventors: SEOKBEOM YONG, Suwon-si (KR); JUWON KIM, Suwon-si (KR); SUNGOH AHN, Suwon-si (KR)

(21) Appl. No.: 19/072,390

(22) Filed: Mar. 6, 2025

(30) Foreign Application Priority Data
Aug. 29, 2024 (KR) 10-2024-0117213

(51) Int. Cl. H01L 23/498

(52) U.S. Cl. CPC H01L 23/49838

(57) ABSTRACT

A package substrate includes: a build-up structure; and a core layer disposed on the build-up structure, wherein the build-up structure includes: a signal ball pad; an interconnection member disposed on the signal ball pad; a signal connection pad disposed on the interconnection member; and a plurality of signal vias and a plurality of signal lines alternately arranged in a vertical direction on the signal connection pad, wherein the interconnection member has a first height in the vertical direction, wherein each of the plurality of signal vias has a second height in the vertical direction, and wherein the first height is greater than the second height.

### CROSS-REFERENCE TO RELATED APPLICATION

This application claims priority under 35 U.S.C. § 119 to Korean Patent Application No. 10-2024-0117213 filed in the Korean Intellectual Property Office on Aug. 29, 2024, the disclosure of which is incorporated by reference herein in its entirety.

### TECHNICAL FIELD

Embodiments of the present inventive concept relate to a package substrate.

### DISCUSSION OF THE RELATED ART

As a high-speed interface IP, such as PCIe or SerDes, is applied to semiconductor packages, a signal characteristic degradation due to an impedance discontinuity of signals that are exiting the package substrate is becoming a problem. The impedance discontinuities may be caused by a stray capacitance in regions other than signal traces of the package substrate, such as areas that include signal ball pads, signal vias, or signal bumps. Among them, the signal ball pad whose area is much larger than that of the signal via or the signal bump causes the generation of an undesirable large value of the stray capacitance between the signal ball pad and a ground plane that is adjacent to the signal ball pad. Since an impedance is inversely proportional to a square root of a capacitance, the stray capacitance that is generated at the signal ball pad may significantly reduce the impedance value compared to a target value, which causes the impedance discontinuity to appear in the region of the signal ball pad.

To address these issues, a package substrate has been under development. For example, a package substrate was designed to remove the ground planes from the signal ball pads so that the signal ball pads and the ground planes do not overlap each other. However, this design introduces areas where only dielectric material exists spanning several hundred micrometers to several millimeters, corresponding to the size of the signal ball pad. These regions may be prone to damage, as cracks can propagate through the dielectric material, potentially compromising the signal routing path.

### SUMMARY

According to an embodiment of the present inventive concept, a package substrate includes: a build-up structure; and a core layer disposed on the build-up structure, wherein the build-up structure includes: a signal ball pad; an interconnection member disposed on the signal ball pad; a signal connection pad disposed on the interconnection member; and a plurality of signal vias and a plurality of signal lines alternately arranged in a vertical direction on the signal connection pad, wherein the interconnection member has a first height in the vertical direction, wherein each of the plurality of signal vias has a second height in the vertical direction, and wherein the first height is greater than the second height.

According to an embodiment of the present inventive concept, a package substrate includes: a build-up structure; and a core layer disposed on the build-up structure, wherein the build-up structure includes: a signal ball pad; a ground ball pad disposed adjacent to the signal ball pad; a signal connection pad spaced apart from the signal ball pad in a first direction by a first interval; a first conductive plane spaced apart from the ground ball pad in the first direction by the first interval and arranged adjacent to the signal connection pad; a signal line spaced apart from the signal connection pad in the first direction by a second interval; and a second conductive plane spaced apart from the first conductive plane in the first direction by the second interval and arranged adjacent to the signal line, wherein the first interval is larger than the second interval.

According to an embodiment of the present inventive concept, a package substrate includes: a first build-up structure; a core layer disposed on the first build-up structure; and a second build-up structure disposed on the core layer, wherein the first build-up structure includes: a signal ball pad; a ground ball pad disposed adjacent to the signal ball pad; a signal interconnection member disposed on the signal ball pad; a ground interconnection member disposed on the ground ball pad and disposed adjacent to the signal interconnection member; a signal connection pad disposed on the signal interconnection member; a plurality of ground planes and a plurality of ground vias alternately arranged in a vertical direction on the ground interconnection member; and a plurality of signal vias and a plurality of signal lines alternately arranged in the vertical direction on the signal connection pad, wherein the signal interconnection member and the ground interconnection member have a first height, wherein each of the plurality of signal vias and each of the plurality of ground vias has a second height, and the first height is greater than the second height.

### BRIEF DESCRIPTION OF THE DRAWINGS

FIG. 1 is a cross-sectional view illustrating a package substrate according to an embodiment of the present inventive concept.

FIG. 2 is an enlarged cross-sectional view of E1 in FIG. 1.

FIG. 3 is a perspective view illustrating a signal routing path within a first build-up structure of FIG. 1.

FIG. 4 is a cross-sectional view illustrating a comparative example of conventional package substrate compared to FIG. 2.

FIG. 5 is a cross-sectional view illustrating a package substrate of an embodiment of the present inventive concept.

FIG. 6 is an enlarged cross-sectional view of E2 in FIG. 5.

FIG. 7 is a perspective view illustrating a signal routing path within a first build-up structure of FIG. 5.

FIG. 8 is a view showing footprints of a signal ball pad, an interconnection member, a signal connection pad, first signal line to sixth signal lines, and a dielectric material region of FIG. 6.

FIG. 9 is a graph comparing an insertion loss of a conventional package substrate and an insertion loss of a package substrate according to an embodiment of present inventive concept.

FIG. 10 is a graph showing a comparison of a reflection loss of a conventional package substrate and a reflection loss of a package substrate according to an embodiment of the present inventive concept.

### DETAILED DESCRIPTION OF THE EMBODIMENTS

Hereinafter, embodiments of the present inventive concept will be described in detail with reference to the attached drawings. Embodiments of the present inventive concept may be embodied in many different forms, and should not be construed as limited to the embodiments set forth herein.

The drawings and description are to be regarded as illustrative in nature and not restrictive. Like reference numerals may designate like elements throughout the specification and drawings.

In the drawings, various thicknesses, lengths, and angles are shown and while the arrangement shown does indeed represent an embodiment of the present inventive concept, it is to be understood that modifications of the various thicknesses, lengths, and angles may be possible within the spirit and scope of the present inventive concept and the present inventive concept is not necessarily limited to the particular thicknesses, lengths, and angles shown.

Throughout this specification and the claims that follow, when it is described that an element is “coupled” to another element, the element may be “directly coupled” to the other element or intervening elements. In addition, if two elements are “coupled” to each other, the elements may be “electrically coupled” to each other.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” means positioned on or below the object portion, and does not necessarily mean positioned on the upper side of the object portion based on a gravitational direction.

Further, throughout the specification, the phrase “in a plan view” means viewing a target portion from the top, unless indicated otherwise, and the phrase “in a cross-sectional view” means viewing a cross-section formed by vertically cutting a target portion from the side.

It is noted that, as used herein, the terms “substantially,” “about,” and other similar terms, are used as terms of approximation, not as terms of degree, and thus are utilized to account for inherent deviations in measured, calculated, and/or provided values that would be recognized by one of ordinary skill in the art.

Hereinafter, a package substrate (100A and 100B) according to an embodiment of the present inventive concept is described with reference to accompanying drawings.

Embodiments of the present inventive concept relate to a package substrate that may enhance signal integrity by addressing issues of impedance discontinuity caused by stray capacitance in semiconductor packages. The issue may originate from the larger surface area of signal ball pads compared to other components, such as signal vias or signal bumps, which may lead to stray capacitance between the signal ball pad and adjacent ground planes. This stray capacitance may result in reduced impedance and signal degradation.

To address the impedance discontinuity, embodiments of the present inventive concept may include an interconnection member with a vertical height that is greater than that of conventional signal vias. This increased spacing may reduce the stray capacitance between the signal ball pad and the adjacent ground plane, increasing the impedance to target levels. Furthermore, the package substrate may include signal connection pads that are smaller in size and positioned to further minimize stray capacitance. For example, conductive planes may be removed from areas overlapping the signal connection pads, allowing the package substrate to balance impedance improvement while avoiding structural vulnerabilities such as cracks in dielectric materials.

According to embodiments of the present inventive concept, the package substrate may include a multi-layer build-up structure including conductive layers, dielectric materials, and signal routing paths. Signal lines may be disposed within openings of ground planes with dielectric material disposed in between the signal lines and the ground planes to ensure proper isolation and minimize interference. The package substrate may further include multiple signal vias, ground vias, and power vias that are alternately stacked with conductive layers to create dedicated paths for signal transmission, grounding, and power delivery. This arrangement may ensure increased signal integrity and overall performance of high-speed interfaces, such as PCIe and SerDes.

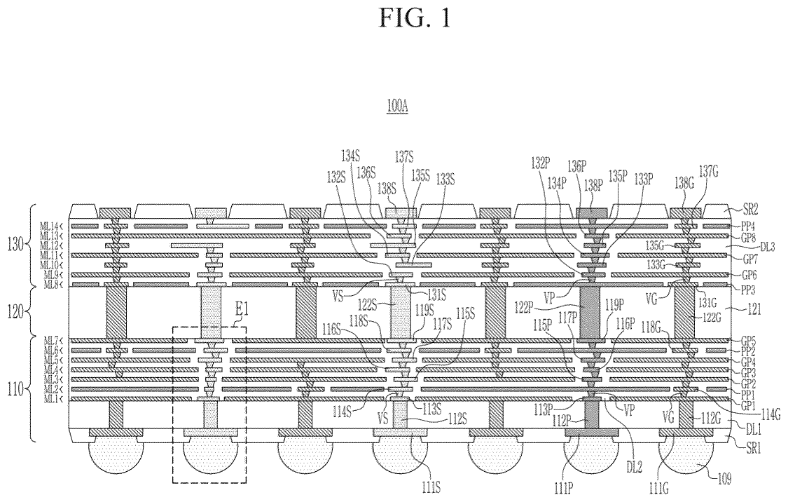

FIG. 1 is a cross-sectional view of a package substrate 100A, according to an embodiment of the present inventive concept.

Referring to FIG. 1, a package substrate 100A may include a connection member 109, a lower build-up structure (a first build-up structure 110), a core layer 120, and an upper build-up structure (a second build-up structure 130). In an embodiment of the present inventive concept, the package substrate 100A may include a printed circuit board (PCB). In an embodiment of the present inventive concept, the package substrate 100A may include a glass substrate or an organic substrate. In an embodiment of the present inventive concept, the package substrate 100A may be a substrate to which a high-speed interface IP such as PCIe or SerDes is applied.

According to the present disclosure, an S is added after a reference numeral of a configuration corresponding to a wiring path that transmits a signal, a G is added after a reference numeral of a configuration corresponding to a wiring path connected to a ground, and a P is added after a reference numeral of a configuration corresponding to a wiring path that transmits an electric power. Additionally, to distinguish between the wiring path that transmits the signals, the wiring path that is connected to the ground, and the wiring path that transmits the electric power, a different pattern is illustrated for each wiring path. Therefore, even if the reference numeral is not indicated, the configuration having the pattern identical to that of the configuration with S appended after the reference numeral indicates the wiring path that transmits the signal, the configuration with the pattern identical to that of the configuration with G added after the reference numeral indicates the wiring path connected to the ground, and the configuration having the pattern identical to that of the configuration with P added after the reference numeral represents the wiring path that transmits the electric power.

The connection members 109 may be placed on the bottom surface of the lower build-up structure 110. The connection members 109 may electrically connect the package substrate 100 to an external device. Each of the connection members 109 may be placed beneath each of the ball pads 111. Each of the connection members 109 may be electrically connected to a corresponding ball pad of the ball pads 111. In an embodiment of the present inventive concept, the connection members 109 may include solder balls. In an embodiment of the present inventive concept, the connection members 109 may include at least one of tin, silver, lead, nickel, copper or an alloy thereof.

The lower build-up structure 110 may include ball pads 111, a first solder resist SR1, interconnection members 112, a first dielectric material layer DL1, sequentially stacked conductive layers ML1 to ML7, vias V (VS, VG, and VP) alternately stacked with the conductive layers ML1 to ML7, and a second dielectric material layer DL2.

Each of the ball pads 111 may be positioned between each of the connection members 109 and each of the interconnection members 112. For example, each of the ball pads 111 may be connected to the corresponding connection member 109 and the corresponding interconnection members 112 while being disposed therebetween. Each of the signal ball pads 111S may be electrically connected to a corresponding signal interconnection member 112S of the signal interconnection members 112S and to a corresponding connection member 109 of the connection members 109. Each of the ground ball pads 111G may be electrically connected to a corresponding ground interconnection member 112G of the ground interconnection members 112G and to a corresponding connection member 109 of the connection members 109. Each of the electric power ball pads 111P may be electrically connected to a corresponding electric power interconnection member 112P of the electric power interconnection members 112P and to a corresponding connection member 109 of the connection members 109. In an embodiment of the present inventive concept, the ball pads 111 may include at least one of copper, nickel, zinc, gold, silver, platinum, palladium, chromium, titanium, and alloys thereof.

The first solder resist SR1 may be placed on the bottom surface of the first dielectric material layer DL1. The first solder resist SR1 serves to prevent the connection members 109 from being short-circuited. The first solder resist SR1 may partially surround and protect the ball pads 111. The first solder resist SR1 may include through-openings exposing ball pads 111. Each of the connection members 109 may be in contact with a corresponding ball pad 111 of the ball pads 111 through the through-opening in the first solder resist SR1.

The interconnection members 112 may be placed within the first dielectric material layer DL1. For example, the interconnection members 112 may be covered by the first dielectric material layer DL1. Each of the signal interconnection members 112S may be placed between a corresponding signal ball pad 111S of the signal ball pads 111S and a corresponding signal connection pad 113 of the signal connection pads 113S. The signal interconnection members 112S may respectively electrically connect each of the signal connection pads 113S to a corresponding signal ball pad 111S of the signal ball pads 111S. Each of the ground interconnection members 112G may be placed between a corresponding ground ball pad 111G of the ground ball pads 111G and the first ground plane GP1. The ground interconnection members 112G may respectively electrically connect the first ground plane (e.g., or layer or pattern) GP1 to a corresponding ground ball pad 111G of the ground ball pads 111G. Each of the electric power interconnection members 112P may be placed between a corresponding electric power ball pad 111P of the electric power ball pads 111P and a corresponding electric power connection pad 113P of the electric power connection pads 113P. The of the electric power interconnection members 112P may respectively electrically connect each of the electric power connection pads 113P to a corresponding electric power ball pad 111P of the electric power ball pads 111P. In an embodiment of the present inventive concept, the interconnection members 112 may include conductive posts. In an embodiment of the present inventive concept, the interconnection members 112 may include at least one of copper, aluminum, tungsten, nickel, gold, tin, titanium, and alloys thereof.

The first dielectric material layer DL1 may at least partially surround the interconnection members 112. In an embodiment of the present inventive concept, the first dielectric material layer DL1 may include synthetic resin-implanted glass cloths such as epoxy-impregnated/immersed woven glass mat (a glass-epoxy), polyimide, FR-4, resin cyanate ester, TEFLON (tetrafluoroethylene) (PTFE), polyethylene ether and a mixture thereof.

The conductive layers ML1 to ML7 may be arranged within the second dielectric material layer DL2. The conductive layers ML1 to ML7 may include a first ground plane GP1, a first electric power plane PP1, a second ground plane GP2, a third ground plane GP3, a fourth ground plane GP4, a second electric power plane PP2, and a fifth ground plane GP5. The first ground plane GP1, the first electric power plane PP1, the second ground plane GP2, the third ground plane GP3, the fourth ground plane GP4, the second electric power plane PP2, and the fifth ground plane GP5 may each be a conductive plane. The conductive layers ML1 to ML7 may be sequentially stacked on the first dielectric material layer DL1. The conductive layers ML1 to ML7 may be arranged spaced apart from each other. For example, the conductive layers ML1 to ML7 may be spaced apart from each other in the vertical direction. The number, arrangement, and configuration of the conductive layers are not limited to the embodiments illustrated and described in the present disclosure, and the conductive layers having the various numbers, arrangements, and configurations may be included within the scope of the present disclosure. For example, an electric power plane may be placed instead of a ground plane, or a ground plane may be placed instead of an electric power plane. Additionally, the conductive layers including any combination of the ground planes and the electric power planes, such as three, five, etc., may be included within the scope of the present disclosure.

In the second dielectric material layer DL2, the signal connection pad 113S, the signal vias VS, the first signal line 114S, the second signal line 115S, the third signal line 116S, the fourth signal line 117S, the fifth signal line 118S, and the sixth signal line 119S may be electrically connected to one another to form a signal routing path. For example, the second dielectric material layer DL2 may cover the signal connection pad 113S, the signal vias VS, the first signal line 114S, the second signal line 115S, the third signal line 116S, the fourth signal line 117S, the fifth signal line 118S, and the sixth signal line 119S. In an embodiment of the present inventive concept, the signal connection pad 113S, the signal vias VS, the first signal line 114S, the second signal line 115S, the third signal line 116S, the fourth signal line 117S, the fifth signal line 118S, and the sixth signal line 119S may each include at least one of copper, aluminum, tungsten, nickel, gold, tin, titanium, and an alloy thereof.

The signal connection pad 113S, the first signal line 114S, the second signal line 115S, the third signal line 116S, the fourth signal line 117S, the fifth signal line 118S, and the sixth signal line 119S may be sequentially stacked from the bottom (e.g., from an upper surface of the first dielectric material layer DL1). The signal vias VS may be stacked alternately in the vertical direction with the signal connection pad 113S, the first signal line 114S, the second signal line 115S, the third signal line 116S, the fourth signal line 117S, the fifth signal line 118S, and the sixth signal line 119S. The signal vias VS, and the signal connection pad 113S, the first signal line 114S, the second signal line 115S, the third signal line 116S, the fourth signal line 117S, the fifth signal line 118S, and the sixth signal line 119S may be electrically connected to each other.

The signal connection pad 113S may be placed in the first conductive layer ML1. The signal connection pad 113S may be located within the opening (a first opening) of the first ground plane GP1. For example, the signal connection pad 113S may be disposed on the same layer as the first ground plane GP1. The first signal line 114S may be placed in the second conductive layer ML2. The first signal line 114S may be placed within the opening of the first electric power plane PP1. For example, the first signal line 114S may be disposed on the same layer as of the first electric power plane PP1. The second signal line 115S may be placed in the third conductive layer ML3. The second signal line 115S may be placed within the opening of the second ground plane GP2. For example, the second signal line 115S may be disposed on the same layer as of the second ground plane GP2. The third signal line 116S may be placed in the fourth conductive layer ML4. The third signal line 116S may be placed within the opening of the third ground plane GP3. For example, the third signal line 116S may be disposed on the same layer as of the third ground plane GP3. The fourth signal line 117S may be placed in the fifth conductive layer ML5. The fourth signal line 117S may be placed within the opening of the fourth ground plane GP4. For example, the fourth signal line 116S may be disposed on the same layer as of the fourth ground plane GP4. The fifth signal line 118S may be placed in the sixth conductive layer ML6. The fifth signal line 118S may be placed within the opening of the second electric power plane PP2. For example, the fifth signal line 118S may be disposed on the same layer as of the second electric power plane PP2. The sixth signal line 119S may be placed in the seventh conductive layer ML7. The sixth signal line 119S may be placed within the opening of the fifth ground plane GP5. For example, the sixth signal line 119S may be disposed on the same layer as of the fifth ground plane GP5.

Within the second dielectric material layer DL2, the first ground plane GP1, the ground vias VG, the first ground line 114G, the second ground plane GP2, the third ground plane GP3, the fourth ground plane GP4, the second ground line 118G, and the fifth ground plane GP5 may be connected to one another to form a ground routing path. For example, the second dielectric material layer DL2 may cover the first ground plane GP1, the ground vias VG, the first ground line 114G, the second ground plane GP2, the third ground plane GP3, the fourth ground plane GP4, the second ground line 118G, and the fifth ground plane GP5. In an embodiment of the present inventive concept, the first ground plane GP1, the ground vias VG, the first ground line 114G, the second ground plane GP2, the third ground plane GP3, the fourth ground plane GP4, the second ground line 118G, and the fifth ground plane GP5 may each include at least one of copper, aluminum, tungsten, nickel, gold, tin, titanium, and an alloy thereof.

The first ground plane GP1, the first ground line 114G, the second ground plane GP2, the third ground plane GP3, the fourth ground plane GP4, the second ground line 118G, and the fifth ground plane GP5 may be stacked sequentially from the bottom (e.g., from an upper surface of the first dielectric material layer DL1). The ground vias VG may be stacked alternately in the vertical direction with the first ground plane GP1, the first ground line 114G, the second ground plane GP2, the third ground plane GP3, the fourth ground plane GP4, the second ground line 118G, and the fifth ground plane GP5. The ground vias VG, and the first ground plane GP1, the first ground line 114G, the second ground plane GP2, the third ground plane GP3, the fourth ground plane GP4, the second ground line 118G, and the fifth ground plane GP5 may be electrically connected to each other.

The first ground plane GP1 may be placed in the first conductive layer ML1. The first ground plane GP1 may include openings, each accommodating either the signal connection pad 113S or the electric power connection pad 113P. The first ground line 114G may be placed in the second conductive layer ML2. The first ground line 114G may be placed within the opening of the first electric power plane PP1. For example, the first ground line 114G may be disposed on the same layer as the first electric power plane PP1. The second ground plane GP2 may be placed in the third conductive layer ML3. The second ground plane GP2 may include openings, each accommodating either the second signal line 115S or the first electric power line 115P. The third ground plane GP3 may be placed in the fourth conductive layer ML4. The third ground plane GP3 may include openings, each accommodating either the third signal line 116S or the second electric power line 116P. The fourth ground plane GP4 may be placed in the fifth conductive layer ML5. The fourth ground plane GP4 may include openings, each accommodating either the fourth signal line 117S or the third electric power line 117P. The second ground line 118G may be placed in the sixth conductive layer ML6. The second ground line 118G may be placed within the opening of the second electric power plane PP2. For example, the second ground line 118G may be disposed on the same layer as the second electric power plane PP2. The fifth ground plane GP5 may be placed in the seventh conductive layer ML7. The fifth ground plane GP5 may include openings, each accommodating either the sixth signal line 119S or the fourth electric power line 119P.

Within the second dielectric material layer DL2, the electric power connection pad 113P, the electric power vias VP, the first electric power plane PP1, the first electric power line 115P, the second electric power line 116P, the third electric power line 117P, the second electric power plane PP2, and the fourth electric power line 119P may be connected to each other to form an electric power routing path. In an embodiment of the present inventive concept, the electric power connection pad 113P, the electric power vias VP, the first electric power plane PP1, the first electric power line 115P, the second electric power line 116P, the third electric power line 117P, the second electric power plane PP2, and the fourth electric power line 119P may include at least one of copper, aluminum, tungsten, nickel, gold, tin, titanium, and alloys thereof.

The electric power connection pad 113P, the first electric power plane PP1, the first electric power line 115P, the second electric power line 116P, the third electric power line 117P, the second electric power plane PP2, and the fourth electric power line 119P may be stacked sequentially from the bottom (e.g., from an upper surface of the first dielectric material layer DL1). The electric power vias VP may be stacked alternately with the electrical power connection pad 113P, the first electric power plane PP1, the first electric power line 115P, the second electric power line 116P, the third electric power line 117P, the second electric power plane PP2, and the fourth electric power line 119P in the vertical direction. The electric power vias VP, and the electric power connection pad 113P, the first electric power plane PP1, the first electric power line 115P, the second electric power line 116P, the third electric power line 117P, the second electric power plane PP2, and the fourth electric power line 119P may be electrically connected to each other.

The electric power connection pad 113P may be placed in the first conductive layer ML1. The electric power connection pad 113P may be placed within the opening of the first ground plane GP1. For example, the electric power connection pad 113P may be disposed on the same layer as the first ground plane GP1. The first electric power plane PP1 may be placed in the second conductive layer ML2. The first electric power plane PP1 may include openings, each accommodating either the first signal line 114S or the first ground line 114G. The first electric power line 115P may be placed in the third conductive layer ML3. The first electric power line 115P may be placed within the opening of the second ground plane GP2. For example, the first electric power line 115P may be disposed on the same layer as the second ground plane GP2. The second electric power line 116P may be placed in the fourth conductive layer ML4. The second electric power line 116P may be placed within the opening of the third ground plane GP3. For example, the second electric power line 116P may be disposed on the same layer as the third ground plane GP3. The third electric power line 117P may be placed in the fifth conductive layer ML5. The third electric power line 117P may be placed within the opening of the fourth ground plane GP4. For example, the third electric power line 117P may be disposed on the same layer as the fourth ground plane GP4. The second electric power plane PP2 may be placed in the sixth conductive layer ML6. The second electric power plane PP2 may include openings, each accommodating either the fifth signal line 118S or the second ground line 118G. The fourth electric power line 119P may be placed in the seventh conductive layer ML7. The fourth electric power line 119P may be placed within the opening of the fifth ground plane GP5. For example, the fourth electric power line 119P may be disposed on the same layer as the fifth ground plane GP5.

In an embodiment of the present inventive concept, the second dielectric material layer DL2 may include synthetic resin-implanted fiber glass cloth, such as epoxy-impregnated/immersed woven glass mat, polyimide, FR-4, resin cyanate ester, TEFLON (tetrafluoroethylene) (PTFE), polyethylene ether, and mixture thereof.

The core layer 120 may be placed on the lower build-up structure 110. The core layer 120 may include a core 121 and core through vias 122. In an embodiment of the present inventive concept, the core 121 may include a glass core, an organic core or a polymer core.

The core through vias 122 may be positioned within the core 121. The core through vias 122 may include signal core through vias 122S, ground core through vias 122G, and electric power core through vias 122P. Each of the signal core through vias 122S may be placed between a corresponding sixth signal line 119S of the sixth signal lines 119S of the lower build-up structure 110 and a corresponding seventh signal line 131S of the seventh signal lines 131S of the upper build-up structure 130. The signal core through vias 122S may respectively electrically connect each of the seventh signal lines 131S of the upper build-up structure 130 to a corresponding sixth signal line 119S of the sixth signal lines 119S of the lower build-up structure 110. Each of the ground core through vias 122G may be placed between the fifth ground plane GP5 of the lower build-up structure 110 and a corresponding third ground line 131G of the third ground lines 131G of the upper build-up structure 130. The ground core through vias 122S may respectively electrically connect each of the third ground lines 131G of the upper build-up structure 130 to the fifth ground plane GP5 of the lower build-up structure 110. Each of the electric power core through vias 122P may be placed between the fourth electric power line 119P of the lower build-up structure 110 and the corresponding third electric power plane PP3 of the third electric power planes PP3 of the upper build-up structure 130. Each of the electric power core through vias 122P may respectively electrically connect each of the third electric power planes PP3 of the upper build-up structure 130 to the fourth electric power line 119P of the lower build-up structure 110.

The core through vias 122 may be formed by a laser machining or a mechanical machining of the core 121. In an embodiment of the present inventive concept, the core through vias 122 may be formed by completely filling the interior of the via hole, which penetrates the core 121, with a conductive material. In an embodiment of the present inventive concept, the core through vias 122 may be formed by conformally forming a conductive material along the inner wall of the via hole and filling the remaining space of the via hole with a dielectric material. In an embodiment of the present inventive concept, the conductive material within the core through vias 122 may include at least one of copper, aluminum, tungsten, nickel, gold, tin, titanium, and alloys thereof. In an embodiment of the present inventive concept, the dielectric material within the core through vias 122 may include synthetic resin-implanted glass cloths such as epoxy-impregnated/immersed woven glass mat (a glass-epoxy), polyimide, FR-4, resin cyanate ester, TEFLON (tetrafluoroethylene) (PTFE), polyethylene ether and a mixture thereof. In an embodiment of the present inventive concept, each of the core through vias 122 may have a width in the horizontal direction ranging from about 30 μm to about 120 μm. The horizontal direction may intersect the vertical direction. In an embodiment of the present inventive concept, the spacing in the horizontal direction between the adjacent core through vias among the core through vias 122 may range from about 200 μm to about 500 μm.

The upper build-up structure 130 may include sequentially stacked conductive layers ML8 to ML14, vias V (VS, VG, and VP) alternately stacked with the conductive layers ML8 to ML14, a third dielectric material layer DL3, a second solder resist SR2, and bonding pads 138.

The conductive layers ML8 to ML14 may be arranged within the third dielectric material layer DL3. The conductive layers ML8 to ML14 may include a third electric power plane PP3, a sixth ground plane GP6, a first signal trace 133S, a seventh ground plane GP7, a second signal trace 135S, an eighth ground plane GP8, and a fourth electric power plane PP4. The conductive layers ML8 to ML14 may be sequentially stacked on the core layer 120. The conductive layers ML8 to ML14 may be arranged spaced apart from each other. For example, the conductive layers ML8 to ML14 may be spaced apart from each other in the vertical direction. The number, arrangement, and configuration of the conductive layers are not limited to the embodiments illustrated and described in the present disclosure, and conductive layers having various numbers, arrangements, and configurations may be included within the scope of the present disclosure. For example, an electric power plane may be placed instead of a ground plane, or a ground plane may be placed instead of an electric power plane. Additionally, the conductive layers including any combination of the ground planes and the electric power planes, such as three, five, etc., may be included within the scope of the present disclosure.

Within the third dielectric material layer DL3, the seventh signal line 131S, the signal vias VS, the eighth signal line 132S, the first signal trace 133S, the ninth signal line 134S, the second signal trace 135S, the tenth signal line 136S, and the eleventh signal line 137S may be electrically connected to one another to form a signal routing path. In an embodiment of the present inventive concept, the seventh signal line 131S, the signal vias VS, the eighth signal line 132S, the first signal trace 133S, the ninth signal line 134S, the second signal trace 135S, the tenth signal line 136S, and the eleventh signal line 137S may each include at least one of copper, aluminum, tungsten, nickel, gold, tin, titanium, and an alloy thereof.

The seventh signal line 131S, the eighth signal line 132S, the first signal trace 133S, the ninth signal line 134S, the second signal trace 135S, the tenth signal line 136S, and the eleventh signal line 137S may be sequentially stacked from the bottom (e.g., from an upper surface of the core layer 120). The signal vias VS may be stacked alternately in the vertical direction with the seventh signal line 131S, the eighth signal line 132S, the first signal trace 133S, the ninth signal line 134S, the second signal trace 135S, the tenth signal line 136S, and the eleventh signal line 137S. The signal vias VS, and the seventh signal line 131S, the eighth signal line 132S, the first signal trace 133S, the ninth signal line 134S, the second signal trace 135S, the tenth signal line 136S, and the eleventh signal line 137S may be electrically connected to each other.

The seventh signal line 131S may be placed in the eighth conductive layer ML8. The seventh signal line 131S may be placed within the opening of the third electric power plane PP3. For example, the seventh signal line 131S may be disposed on the same layer as the third electric power plane PP3. The eighth signal line 132S may be placed in the ninth conductive layer ML9. The eighth signal line 132S may be placed within the opening of the sixth ground plane GP6. For example, the eighth signal line 132S may be disposed on the same layer as the sixth ground plane GP6. The first signal trace 133S may be placed in the tenth conductive layer ML10. The first signal trace 133S may route one of a Rx signal or a Tx signal. The ninth signal line 134S may be placed in the eleventh conductive layer ML11. The ninth signal line 134S may be placed within the opening of the seventh ground plane GP7. For example, the ninth signal line 134S may be disposed on the same layer as the seventh ground plane GP7. The second signal trace 135S may be placed in the twelfth conductive layer ML12. The second signal trace 135S may route the other of the Rx signal or the Tx signal. The tenth signal line 136S may be placed in the thirteenth conductive layer ML13. The tenth signal line 136S may be placed within the opening of the eighth ground plane GP8. For example, the tenth signal line 136S may be disposed on the same layer as the eighth ground plane GP8. The eleventh signal line 137S may be placed in the fourteenth conductive layer ML14. The eleventh signal line 137S may be placed within the opening of the fourth electric power plane PP4. For example, the eleventh signal line 137S may be disposed on the same layer as the fourth electric power plane PP4.

Within the third dielectric material layer DL3, the third ground line 131G, the ground vias VG, the sixth ground plane GP6, the fourth ground line 133G, the seventh ground plane GP7, the fifth ground line 135G, the eighth ground plane GP8, and the sixth ground line 137G may be connected to each other to form a ground routing path. In an embodiment of the present inventive concept, the third ground line 131G, the ground vias VG, the sixth ground plane GP6, the fourth ground line 133G, the seventh ground plane GP7, the fifth ground line 135G, the eighth ground plane GP8, and the sixth ground line 137G may each include at least one of copper, aluminum, tungsten, nickel, gold, tin, titanium, and an alloy thereof.

Third ground line 131G, the sixth ground plane GP6, the fourth ground line 133G, the seventh ground plane GP7, the fifth ground line 135G, the eighth ground plane GP8, and the sixth ground line 137G may be stacked sequentially from the bottom. The ground vias VG may be stacked alternately in the vertical direction with the third ground line 131G, the sixth ground plane GP6, the fourth ground line 133G, the seventh ground plane GP7, the fifth ground line 135G, the eighth ground plane GP8, and the sixth ground line 137G. The ground vias VG, and the third ground line 131G, the sixth ground plane GP6, the fourth ground line 133G, the seventh ground plane GP7, the fifth ground line 135G, the eighth ground plane GP8, and the sixth ground line 137G may be electrically connected to each other.

The third ground line 131G may be placed in the eighth conductive layer ML8. The third ground line 131G may be placed within the opening of the third electric power plane PP3. The sixth ground plane GP6 may be placed in the ninth conductive layer ML9. The sixth ground plane GP6 may include openings, each accommodating either the eighth signal line 132S or the fifth electric power line 132P. The fourth ground line 133G may be placed in the tenth conductive layer ML10. The seventh ground plane GP7 may be placed in the eleventh conductive layer ML11. The seventh ground plane GP7 may include openings, each accommodating either the ninth signal line 134S or the seventh electric power line 134P. The fifth ground line 135G may be placed in the twelfth conductive layer ML12. The eighth ground plane GP8 may be placed in the thirteenth conductive layer ML13. The eighth ground plane GP8 may include openings, each accommodating either the tenth signal line 136S or the ninth electric power line 136P. The sixth ground line 137G may be placed in the fourteenth conductive layer ML14. The sixth ground line 137G may be placed within the opening of the fourth electric power plane PP4.

Within the third dielectric material layer DL3, the third electric power plane PP3, the electric power vias VP, the fifth electric power line 132P, the sixth electric power line 133P, the seventh electric power line 134P, the eighth electric power line 135P, the ninth electric power line 136P, and the fourth electric power plane PP4 may form an electric power routing path. In an embodiment, the third electric power plane PP3, the electric power vias VP, the fifth electric power line 132P, the sixth electric power line 133P, the seventh electric power line 134P, the eighth electric power line 135P, the ninth electric power line 136P, and the fourth electric power plane PP4 may include at least one of copper, aluminum, tungsten, nickel, gold, tin, titanium, and alloys thereof.

The third electric power plane PP3, the fifth electric power line 132P, the sixth electric power line 133P, the seventh electric power line 134P, the eighth electric power line 135P, the ninth electric power line 136P, and the fourth electric power plane PP4 may be stacked sequentially from the bottom (e.g., from an upper surface of the core layer 120). The electric power vias VP may be stacked alternately with the third electric power plane PP3, the fifth electric power line 132P, the sixth electric power line 133P, the seventh electric power line 134P, the eighth electric power line 135P, the ninth electric power line 136P, and the fourth electric power plane PP4 in the vertical direction. The electric power vias VP, and the third electric power plane PP3, the fifth electric power line 132P, the sixth electric power line 133P, the seventh electric power line 134P, the eighth electric power line 135P, the ninth electric power line 136P, and the fourth electric power plane PP4 may be electrically connected to each other.

The third electric power plane PP3 may be placed in the eighth conductive layer ML8. The third electric power plane PP3 may include openings, each accommodating either the seventh signal lines 131S or the third ground line 131G. The fifth electric power line 132P may be placed in the ninth conductive layer ML9. The fifth electric power line 132P may be placed within the opening of the sixth ground plane GP6. For example, the fifth electric power line 132P may be disposed on the same layer as the sixth ground plane GP6. The sixth electric power line 133P may be placed in the tenth conductive layer ML10. The seventh electric power line 134P may be placed in the eleventh conductive layer ML11. The seventh electric power line 134P may be placed within the opening of the seventh ground plane GP7. For example, the seventh electric power line 134P may be disposed on the same layer as the seventh ground plane GP7. The eighth electric power line 135P may be placed in the twelfth conductive layer ML12. The ninth electric power line 136P may be arranged in the thirteenth conductive layer ML13. The ninth electric power line 136P may be placed within the opening of the eighth ground plane GP8. For example, the ninth electric power line 136P may be disposed on the same layer as the eighth ground plane GP8. The fourth electric power plane PP4 may be placed in the fourteenth conductive layer ML14. The fourth electric power plane PP4 may include openings, each accommodating either the eleventh signal line 137S or the sixth ground line 137G may be placed.

In an embodiment of the present inventive concept, the third dielectric material layer DL3 may include synthetic resin impregnated fiber glass cloth, such as epoxy-impregnated/immersed woven glass mat, polyimide, FR-4, resin cyanate ester, TEFLON (tetrafluoroethylene) (PTFE), polyethylene ether, and mixture thereof.

The bonding pads 138 may be placed on the third dielectric material layer DL3. For example, a semiconductor chip may be mounted on the bonding pads 138. Each of the signal bonding pads 138S may be positioned on a corresponding signal via VS of the signal vias VS and be electrically connected to of the corresponding signal via VS. Each of the ground bonding pads 138G may be positioned on a corresponding ground via VG of the ground vias VG and be electrically connected to the corresponding ground via VG. Each of the electric power bonding pads 138P may be positioned on a corresponding electric power via VP of the electric power vias VP and be electrically connected to the corresponding electric power via VP. In an embodiment of the present inventive concept, the bonding pads 138 may each include at least one of copper, aluminum, tungsten, nickel, gold, tin, titanium, and alloys thereof.

The second solder resist SR2 may be placed on the upper surface of the third dielectric material layer DL3. The second solder resist SR2 may prevent the connection members, of a semiconductor chip, connecting the package substrate 100A and the semiconductor chip from being short-circuited. The second solder resist SR2 may partially surround and protect bonding pads 138. The second solder resist SR2 may include through openings that expose the bonding pads 138.

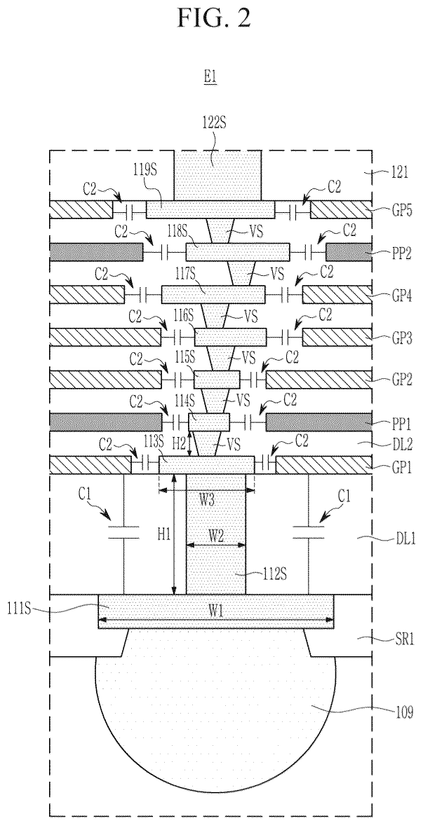

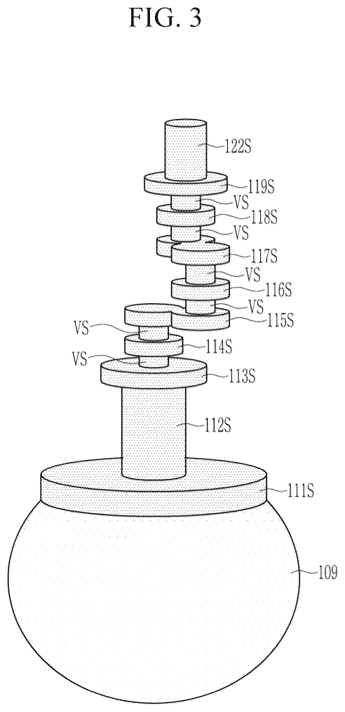

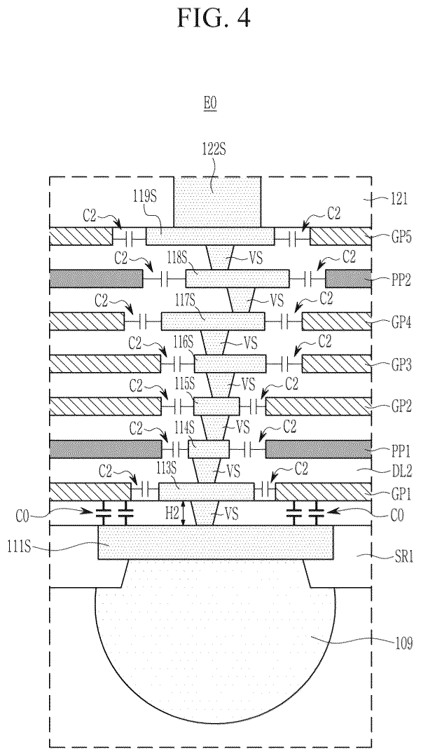

FIG. 2 is an enlarged cross-sectional view of E1 in FIG. 1. FIG. 3 is a perspective view illustrating a signal routing path within a lower build-up structure 110 of FIG. 1. FIG. 4 is a cross-sectional view illustrating a comparative example of a conventional package substrate compared with FIG. 2.

Referring to FIG. 2 and FIG. 3, the signal ball pad 111S according to an embodiment of the present inventive concept may be positioned to be spaced apart from the first ground plane GP1 by a height that is equal to a height H1 of the interconnection member 112S. Since the signal ball pad 111S is electrically isolated or insulated from the first ground plane GP1, and the first dielectric material layer DL1 is placed between the signal ball pad 111S and the first ground plane GP1, a first stray capacitance C1 may be generated between the signal ball pad 111S and the first ground plane GP1.

In comparison, referring to FIG. 4, the signal ball pad 111S according to a comparative example may be arranged to be spaced apart from the first ground plane GP1 by a height that is equal to a height H2 of the signal via VS. Since the signal ball pad 111S is electrically isolated from the first ground plane GP1, and the second dielectric material layer DL2 is placed between the signal ball pad 111S and the first ground plane GP1, a fourth stray capacitance C0 may be generated between the signal ball pad 111S and the first ground plane GP1.

The magnitude of the first stray capacitance C1 is inversely proportional to the distance between two conductive materials that are separated by a dielectric material. Since the distance H2 between the signal ball pad 111S and the first ground plane GP1 according to a comparative example is relatively small, the fourth stray capacitance C0 with a large value may be generated between the signal ball pad 111S and the first ground plane GP1. Thus, the fourth stray capacitance C0 having the large value may significantly reduce the impedance value compared to a target value, which causes an impedance discontinuity to appear in the region of the signal ball pad 111S. This impedance discontinuity can degrade signal integrity, leading to issues such as increased signal loss, reflection, and interference, which may adversely affect the performance of high-speed interfaces like PCIe or SerDes.

To address this issue, according to an embodiment of the present inventive concept, the interconnection member 112S having the height H1, which is greater than the height H2 of the signal via VS that separates the signal ball pad 111S and the first ground plane GP1 from each other according to the comparative example, is placed between the signal ball pad 111S and the first ground plane GP1 to increase the interval between the signal ball pad 111S and the first ground plane GP1, thereby reducing the magnitude of the first stray capacitance C1 that is generated between the signal ball pad 111S and the first ground plane GP1. This may improve the impedance discontinuity appearing in the signal ball pad 111S region and enhance the signal characteristics. By increasing the separation between the signal ball pad 111S and the first ground plane GP1, a more stable impedance value that is closer to the target may be achieved. This not only mitigates signal degradation but may also enhance the overall performance and reliability of high-speed signal transmission within the package substrate.

In an embodiment of the present inventive concept, the height (the first height; H1) of the signal interconnection member 112S, the height of the ground interconnection member 112G, and/or the height of the electric power interconnection member 112P in the vertical direction may range from about 200 μm to about 300 μm. For example, each of the height of the ground interconnection member 112G and the height of the electric power interconnection member 112P may be equal to the first height H1. In an embodiment of the present inventive concept, the spacing (first spacing H1) between the signal ball pad 111S and the first ground plane GP1 in the vertical direction, the spacing between the signal ball pad 111S and the signal connection pad 113S in the vertical direction, the spacing between the ground ball pad 111G and the first ground plane GP1 in the vertical direction, and/or the spacing between the electric power ball pad 111P and the first ground plane GP1 in the vertical direction may range from about 200 μm to about 300 μm. For example, each of the spacing between the signal ball pad 111S and the signal connection pad 113S in the vertical direction, the spacing between the ground ball pad 111G and the first ground plane GP1 in the vertical direction, and the spacing between the electric power ball pad 111P and the electric power connection pad 113P in the vertical direction may be equal to the first spacing H1. In an embodiment of the present inventive concept, the height (a second height H2) of the signal via VS, the height of the ground via VG and/or the height of the electric power via VP in the vertical direction may range from about 5 μm to about 50 μm. For example, the height (a second height H2) of the signal via VS, the height of the ground via VG and/or the height of the electric power via VP in the vertical direction may be substantially the same as one another. In an embodiment of the present inventive concept, the spacing between the signal connection pad 113S and the first signal line 114S in the vertical direction and a spacing (a second spacing H2) between the first ground plane GP1 and the first electric power plane PP1 in the vertical direction may range from about 5 μm to about 50 μm. For example, the spacing between the signal connection pad 113S and the first signal line 114S in the vertical direction and the spacing (a second spacing H2) between the first ground plane GP1 and the first electric power plane PP1 in the vertical direction may be substantially the same as each other. The magnitude of the first stray capacitance C1 is inversely proportional to the distance between two conductive materials that are separated by the dielectric material, and the impedance value is inversely proportional to a square root of the capacitance value. Based on this, test results showed that the spacing H1 between the signal ball pad 111S and the first ground plane GP1, which may reduce the first stray capacitance C1 and improve the impedance value to the target impedance value, should be approximately 200 μm or more. In addition, considering the thickness of the package substrate 100A, it may be desirable that the spacing H1 between the increased signal ball pad 111S and the first ground plane GP1 be less than about 300 μm.

The signal connection pad 113S, the first signal line 114S, the second signal line 115S, the third signal line 116S, the fourth signal line 117S, the fifth signal line 118S, and the sixth signal line 119S within the signal routing path may be sequentially stacked and alternately stacked with the signal vias VS in the vertical direction to be electrically connected to each other. The signal connection pad 113S and the first ground plane GP1 may be electrically isolated from each other, and the second dielectric material layer DL2 may be disposed between them, so that the second stray capacitance C2 may be generated between them. The first signal line 114S and the first electric power plane PP1 may be electrically isolated from each other, and the second dielectric material layer DL2 may be disposed between them, so that the second stray capacitance C2 may be generated between them. The second signal line 115S and the second ground plane GP2 may be electrically isolated from each other, and the second dielectric material layer DL2 may be disposed between them, so that the second stray capacitance C2 may be generated between them. The third signal line 116S and the third ground plane GP3 may be electrically isolated from each other, and the second dielectric material layer DL2 may be disposed between them, so that the second stray capacitance C2 may be generated between them. The fourth signal line 117S and the fourth ground plane GP4 may be electrically isolated from each other, and the second dielectric material layer DL2 may be disposed between them, so that the second stray capacitance C2 may be generated between them. The fifth signal line 118S and the second electric power plane PP2 may be electrically isolated from each other, and the second dielectric material layer DL2 may be disposed between them, so that the second stray capacitance C2 may be generated between them. The sixth signal line 119S and the fifth ground plane GP5 may be electrically isolated from each other, and the second dielectric material layer DL2 may be disposed between them, so that the second stray capacitance C2 may be generated between them. However, the second stray capacitance C2 is smaller in value compared to the first stray capacitance C1, which is generated between the signal ball pad 111S, having the larger magnitude, and the first ground plane GP1.

The width W1 of the signal ball pad 111S, the width of the ground ball pad 111G and/or the width of the electric power ball pad 111P in the horizontal direction may be greater than the width (a second width W3) of the signal connection pad 113S in the horizontal direction. For example, the width W1 of the signal ball pad 111S, the width of the ground ball pad 111G and the width of the electric power ball pad 111P in the horizontal direction may be substantially the same as each other. In an embodiment of the present inventive concept, the width (the first width W1) of the signal ball pad 111S, the width of the ground ball pad 111G and/or the width of the electric power ball pad 111P in the horizontal direction may range from about 400 μm to about 800 μm. In an embodiment of the present inventive concept, the width W2 of the signal interconnection member 112S, the width of the ground interconnection member 112G and/or the width of the electric power interconnection member 112P in the horizontal direction may range from about 20 μm to about 200 μm. For example, the width W2 of the signal interconnection member 112S, the width of the ground interconnection member 112G and the width of the electric power interconnection member 112P in the horizontal direction may be substantially the same as each other. In an embodiment of the present inventive concept, the width (the second width W3) of the signal connection pad 113S in the horizontal direction may range from about 100 μm to about 300 μm.

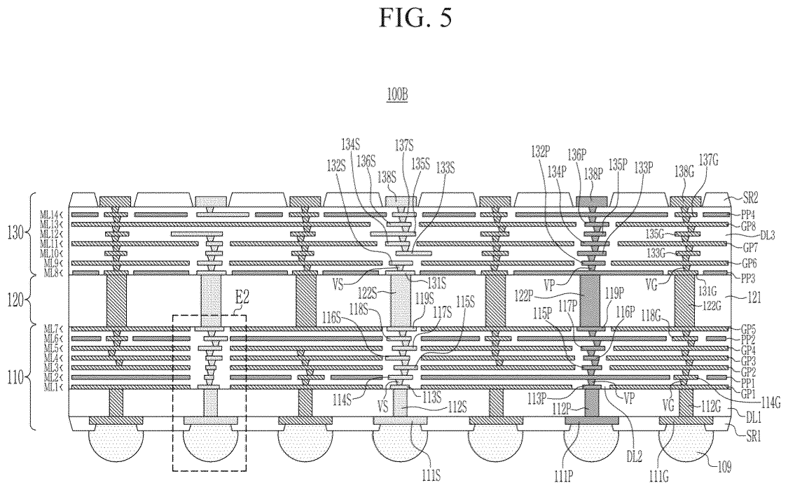

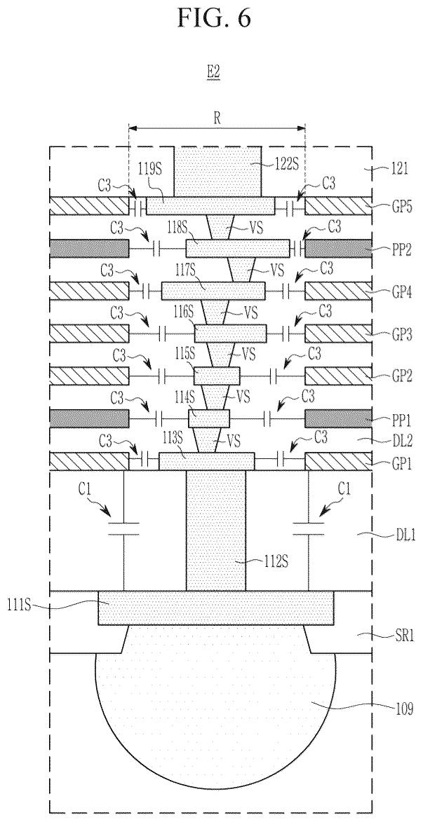

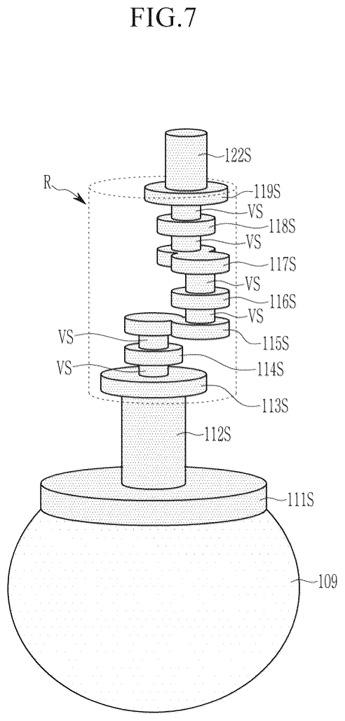

FIG. 5 is a cross-sectional view of a package substrate 100B of an embodiment of the present inventive concept. FIG. 6 is an enlarged cross-sectional view of E2 in FIG. 5. FIG. 7 is a perspective view illustrating a signal routing path within a lower build-up structure 110 of FIG. 5.

Referring to FIG. 5, FIG. 6, and FIG. 7, a package substrate 100B may include a dielectric material region R without a ground plane or an electric power plane around the signal routing path. The dielectric material region R can have a width in the horizontal direction smaller than the width W1 of the signal ball pad 111S in the horizontal direction.

Due to this, the distance between the signal connection pad 113S and the first ground plane GP1, the distance between the first signal line 114S and the first electric power plane PP1, the distance between the second signal line 115S and the second ground plane GP2, the distance between the third signal line 116S and the third ground plane GP3, the distance between the fourth signal line 117S and the fourth ground plane GP4, the distance between the fifth signal line 118S and the second electric power plane PP2, and the distance between the sixth signal line 119S and the fifth ground plane GP5 may all increase, so that the third stray capacitance C3 generated between them may be reduced. The third stray capacitance C3 may have a value smaller than the value of the second stray capacitance C2 in the embodiment of FIG. 1.

In this way, the package substrate 100B according to an embodiment of the present inventive concept may reduce the third stray capacitance C3 value generated around the signal routing path by including a dielectric material region R in which a larger amount of dielectric material exists around the signal routing path. Additionally, since the dielectric material region R has the width smaller than the width W1 of the signal ball pad 111S in the horizontal direction, the signal routing path may be prevented from being damaged by a crack propagating into the dielectric material.

The description of the package substrate 100A of an embodiment of FIG. 1 to FIG. 4 may be applied to the package substrate 100B of an embodiment of FIG. 5.

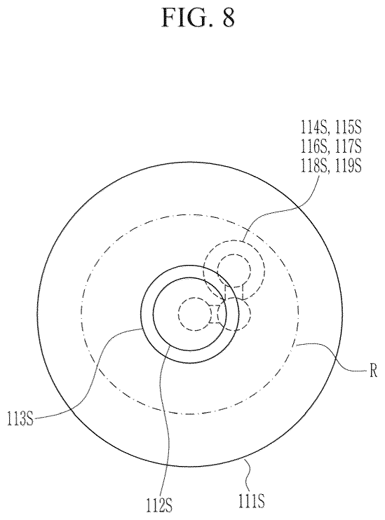

FIG. 8 is a drawing showing footprints (e.g., outlines) of a signal ball pad 111S, a signal interconnection member 112S, a signal connection pad 113S, a first signal line to sixth signal line 114S, 115S, 116S, 117S, 118S, and 119S, and a dielectric material region R of FIG. 6.

Referring to FIG. 6, FIG. 7, and FIG. 8, the footprints (e.g., outlines) of a first opening of a first ground plane GP1 where the signal connection pad 113S is arranged, a second opening of a first electric power plane PP1 where the first signal line 114S is arranged, a third opening of a second ground plane GP2 where the second signal line 115S is arranged, a fourth opening of a third ground plane GP3 where the third signal line 116S is arranged, a fifth opening of a fourth ground plane GP4 where the fourth signal line 117S is arranged, a sixth opening of a second electric power plane PP2 where the fifth signal line 118S is arranged, and a seventh opening of a fifth ground plane GP5 where the sixth signal line 119S is arranged may coincide with each other. These footprints may match the footprint of the dielectric material region R. For example, the dielectric material region R may be defined by the first opening of a first ground plane GP1, the second opening of a first electric power plane PP1, a third opening of a second ground plane GP2, a fourth opening of a third ground plane GP3, a fifth opening of a fourth ground plane GP4, a sixth opening of a second electric power plane PP2, and a seventh opening of a fifth ground plane GP5. For example, the width of the dielectric material region R may be substantially equal to the width of each of the first to seventh openings.

The footprint of each of the signal connection pad 113S, the first signal line 114S, the second signal line 115S, the third signal line 116S, the fourth signal line 117S, the fifth signal line 118S, and the sixth signal line 119S may overlap the footprint of the dielectric material region R. For example, the footprint of the dielectric material region R may be larger than the footprint of each of the signal connection pad 113S, the first signal line 114S, the second signal line 115S, the third signal line 116S, the fourth signal line 117S, the fifth signal line 118S, and the sixth signal line 119S. The footprint of each of the signal connection pad 113S, the first signal line 114S, the second signal line 115S, the third signal line 116S, the fourth signal line 117S, the fifth signal line 118S, and the sixth signal line 119S might not overlap the footprint of each of the first ground plane GP1, the first electric power plane PP1, the second ground plane GP2, third ground plane GP3, the fourth ground plane GP4, the second electric power plane PP2, and the fifth ground plane GP5.

The footprint of each of the first ground plane GP1, the first electric power plane PP1, the second ground plane GP2, the third ground plane GP3, the fourth ground plane GP4, the second electric power plane PP2, and the fifth ground plane GP5 may overlap the footprint of the signal ball pad 111S.

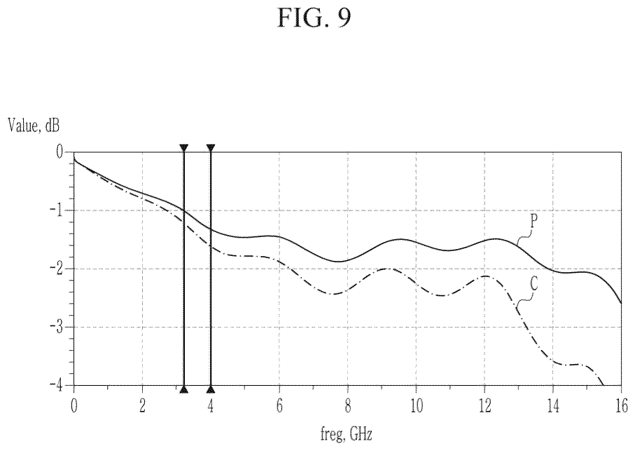

FIG. 9 is a graph showing a comparison of an insertion loss of a conventional package substrate and an insertion loss of a package substrate according to an embodiment of the present inventive concept.

Referring to FIG. 9, tested results show the insertion loss of an embodiment P, in which the signal ball pad 111S and the first ground plane GP1 are spaced apart in the vertical direction to have the spacing gap H1 according to an embodiment of the present inventive concept, and the insertion loss of a comparative example C, in which the signal ball pad 111S and the first ground plane GP1 are spaced apart in the vertical direction to have a conventional gap H2.

As a result of the test, at a frequency of 3.2 GHZ, the insertion loss according to the comparative example C was measured to be approximately-1.22 dB, and the insertion loss of the embodiment P according to an embodiment of the present inventive concept was measured to be approximately-1.00 dB. In addition, at a frequency of 4 GHZ, the insertion loss according to the comparative example C was measured to be about-1.61 dB, and the insertion loss of the embodiment P according to an embodiment of the present inventive concept was measured to be about-1.30 dB. Therefore, according to an embodiment of the present inventive concept, the insertion loss may be improved by about 18% and the signal characteristics may be improved.

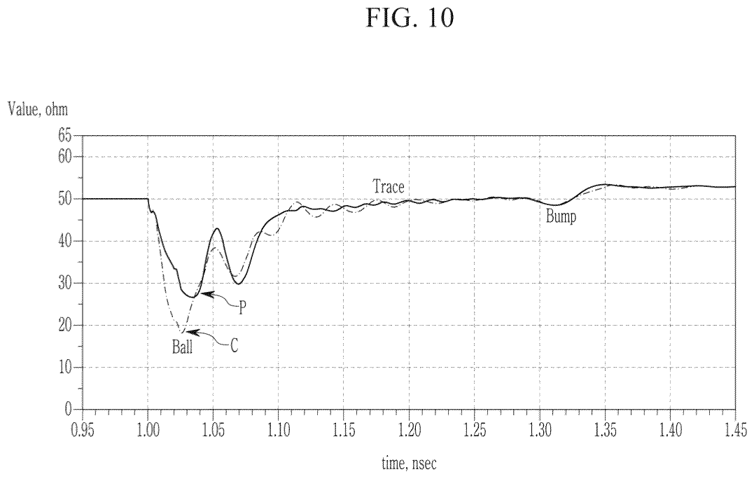

FIG. 10 is a graph showing a comparison of a reflection loss of a conventional package substrate and a reflection loss of a package substrate according to an embodiment of the present inventive concept.

Referring to FIG. 10, a time-domain reflectometry (TDR), which derives an impedance by calculating signals reflected from a signal ball pad region, a signal trace region, and a bump region, was tested for an embodiment P according to an embodiment of the present inventive concept and a conventional comparative example C.

In the ball region, the impedance value according to the comparative example C was 18 ohm, which was much lower than a target impedance of approximately 50 ohm, and an impedance discontinuity characteristic was significantly displayed. In contrast, in the ball region according to an embodiment of the present inventive concept, the test results show an impedance value of approximately 26 ohms, indicating both an improvement in impedance value and a reduction in impedance discontinuity. In the trace region and the bump region, it may be seen that the impedance value according to the comparative example C and the impedance value of the embodiment P according to an embodiment of the present inventive concept represent the target impedance of approximately 50 ohm.

While the present inventive concept has been described with reference to example embodiments thereof, it will be understood by those of ordinary skill in the art that various changes in form and details may be made thereto without departing from the spirit and scope of the present inventive concept.

What is claimed is:

1. A package substrate comprising:
a build-up structure; and
a core layer disposed on the build-up structure,
wherein the build-up structure includes:
a signal ball pad;
an interconnection member disposed on the signal ball pad;
a signal connection pad disposed on the interconnection member; and
a plurality of signal vias and a plurality of signal lines alternately arranged in a vertical direction on the signal connection pad,
wherein the interconnection member has a first height in the vertical direction,
wherein each of the plurality of signal vias has a second height in the vertical direction, and
wherein the first height is greater than the second height.

2. The package substrate of claim 1, wherein:
the first height ranges from about 200 μm to about 300 μm.

3. The package substrate of claim 1, wherein:
the second height ranges from about 5 μm to about 50 μm.

4. The package substrate of claim 1, wherein:
the signal ball pad has a first width in a horizontal direction that intersects the vertical direction,
wherein the signal connection pad has a second width in the horizontal direction, and
wherein the first width is larger than the second width.

5. The package substrate of claim 1, wherein:
the signal connection pad has a width ranging from about 100 μm to about 300 μm in a horizontal direction that intersects the vertical direction.

6. The package substrate of claim 1, wherein:
the interconnection member has a width ranging from about 20 μm to about 200 μm in a horizontal direction that intersects the vertical direction.

7. The package substrate of claim 1, wherein:
the signal ball pad has a width ranging from about 400 μm to about 800 μm in a horizontal direction that intersects the vertical direction.

8. The package substrate of claim 1, wherein:
the interconnection member includes a conductive post.

9. A package substrate comprising:
a build-up structure; and
a core layer disposed on the build-up structure,
wherein the build-up structure includes:
a signal ball pad;
a ground ball pad disposed adjacent to the signal ball pad;
a signal connection pad spaced apart from the signal ball pad in a first direction by a first interval;
a first conductive plane spaced apart from the ground ball pad in the first direction by the first interval and arranged adjacent to the signal connection pad;
a signal line spaced apart from the signal connection pad in the first direction by a second interval; and
a second conductive plane spaced apart from the first conductive plane in the first direction by the second interval and arranged adjacent to the signal line,
wherein the first interval is larger than the second interval.

10. The package substrate of claim 9, wherein:
the first interval ranges from about 200 μm to about 300 μm.

11. The package substrate of claim 9, wherein:
the second interval ranges from about 5 μm to about 50 μm.

12. The package substrate of claim 9, wherein:
the first conductive plane includes a ground plane.

13. The package substrate of claim 9, wherein:
the second conductive plane includes an electric power plane.

14. The package substrate of claim 9, wherein:
the first conductive plane includes a first opening, and the signal connection pad is disposed within the first opening,
the second conductive plane includes a second opening, and the signal line is disposed within the second opening, and
an outline of the first opening matches an outline of the second opening.

15. The package substrate of claim 9, wherein:
the signal connection pad does not overlap the second conductive plane.

16. A package substrate comprising:
a first build-up structure;
a core layer disposed on the first build-up structure; and
a second build-up structure disposed on the core layer,
wherein the first build-up structure includes:
a signal ball pad;
a ground ball pad disposed adjacent to the signal ball pad;
a signal interconnection member disposed on the signal ball pad;
a ground interconnection member disposed on the ground ball pad and disposed adjacent to the signal interconnection member;
a signal connection pad disposed on the signal interconnection member;
a plurality of ground planes and a plurality of ground vias alternately arranged in a vertical direction on the ground interconnection member; and
a plurality of signal vias and a plurality of signal lines alternately arranged in the vertical direction on the signal connection pad,
wherein the signal interconnection member and the ground interconnection member have a first height,
wherein each of the plurality of signal vias and each of the plurality of ground vias has a second height, and
the first height is greater than the second height.

17. The package substrate of claim 16, wherein:
the first build-up structure further includes:
a first dielectric material layer covering the signal interconnection member and the ground interconnection member; and
a second dielectric material layer covering the signal connection pad, the plurality of signal vias, the plurality of signal lines, the plurality of ground planes, and the plurality of ground vias.

18. The package substrate of claim 16, wherein:
the core layer includes a core and a plurality of core through vias,
wherein the plurality of core through vias includes:
a plurality of signal core through vias connected to the plurality of signal lines; and
a plurality of ground core through vias connected to the plurality of ground planes.

19. The package substrate of claim 16, wherein:
the plurality of signal lines does not overlap the plurality of ground planes.

20. The package substrate of claim 19, wherein:
the signal ball pad overlaps the plurality of ground planes.
